(19) United States
(12) Patent Application Publication
(10) Pub. No.: US 2012/0026696 A1
(43) Pub. Date: Feb. 2, 2012

(54) Multilayer packagings

(75) Inventors: Jukka Hillberg, Tampere (FI); Jouni Hillberg, Tampere (FI); Jyri Nieminen, Tampere (FI)

(73) Assignee: IONPHASE OY, Tampere (FI)

(21) Appl. No.: 12/991,127

(22) PCT Filed: May 5, 2009
(86) PCT No.: PCT/FI2009/050361

§ 371 Date: May 26, 2011

(30) Foreign Application Priority Data
May 5, 2008 (FI) 20085407

(51) Int. Cl. H05K 7/00

(52) U.S. Cl. 361/746

(57) ABSTRACT

An ungrounded type multilayer packaging with a reduced energy of electrostatic discharge for packaging used in a combustible environment. The packaging comprises a non-conductive multilayer packaging material containing at least one polymeric thermoplastic electrostatic dissipating layer, to give an electrostatic discharge energy attenuation of more than 40 dB.

### BACKGROUND OF THE INVENTION

1. Field of the Invention

The present invention relates to multilayer packagings. In particular, the invention concerns a multilayer packaging with a reduced energy of electrostatic discharges suitable for use in IBCs and bags for explosion and other hazard zones and that does not especially need to be grounded.

2. Description of Related Art

Intermediate bulk containers (IBC) are commonly used for packaging various powders and granulate-form products. Typically, RIBCs (rigid intermediate bulk containers) are made of high density polyethylene or polypropylene, whereas FIBCs (flexible intermediate bulk containers) are made of knitted polyethylene or polypropylene fabric. These types of materials are insulators and they have strong tribo charging property. During filling and discharging of products, both product and packages are charging up. High electrostatic fields can be measured from the packaging surface.

The system formed by the IBCs and packaged products has also high charge density. This gives rise to a situation where at use electrostatic discharges (ESD) can occur. The energy, depending on the form of these discharges, can be higher than the minimum ignition energy (MIE) of the packaged product or surrounding atmosphere. Minimum ignition energy is defined as the smallest electrical energy stored in a capacitor, which is sufficient to ignite the most willing mixture of combustible material (gas or dust) and air under normal pressure and room temperature when discharging via a spark range. It is determined in varying the parameters of the discharge formula; capacity, charge voltage, shape and distance of the electrodes and duration of the discharge. If the mentioned ESD condition occurs, it can result an explosion or fire of the product or surrounding atmosphere.

The maximum allowed discharge energy for explosion groups IIA and IIB are in the range of from 0.1 mJ to 0.3 mJ. The most sensitive gases or vapors of explosion group IIC can be as low as 0.01 to 0.02 mJ.

The maximum allowed transmitted charge (nC) of electrostatic discharges for different explosion groups determined in EN50014 yields from the following table of EN13463-1:

TABLE 1

| Explosion | | | | |
|---|---|---|---|---|
| groups (EN50014) | I (nC) | IIA (nC) | IIB (nC) | IIC (nC) |
| Maximum allowed | 60 | 60 | 30 | 10 |
| transmitted charge | | | | |

### Known Solutions:

FIBC type C; In this solution part of the yarns has been replaced with electrically conductive ones so that they from an interconnected grid in the fabric. These conductive yarns are typically in 5 cm mesh. Standard IEC 61340-4-4 specify that the surface resistance to grounding point has to be less than 1×10⁸ ohms from any point of the fabric. C type FIBC has to be grounded in any circumstance when in use.

If the connection to ground is lost, this type FIBC becomes very dangerous because of high density of mobile charges on the fabric.

FIBC type D; In this solution the yarns have conductive fillers or fibers with correct size and shape, like steel or carbon fibers or conductive yarns. Above threshold level of breakdown field strength to air, energy is dissipating via corona discharges from the sharp ends of these particles or fibers. The energy of these discharges is controlled by the size of the conductive fillers or fibers. Energy of these continuous discharges has to be below the minimum ignition energy of the packaged product. This is reducing the charge density and therefore the surface potential of the fabric. This solution is used without grounding. Standard IEC 61340-4-4 is specifying the requirements for type D FIBC for safe use. Current manufacturers for this solution include at least Crohmiq and Sunjut.

The distribution of the conductive fibers or fillers is hard to control during the conversion stage. The fibers' or fillers' percolation can vary and this could give the opportunity for discharges with higher energy than MIE to form.

In the past, various methods have been employed to produce anti-static woven fabrics suitable for flexible intermediate bulk containers, FIBC. They are designed to be handled with standard fork-lifts and typically hold from 200 to 1250 kg of material.

A common hazard of IBCs is electrostatic discharge (ESD). ESD hazard ranges from personnel electric shocks to sparks capable of igniting explosive mixtures of dust or flammable gases. As a result it is necessary to eliminate ESD from flexible intermediate bulk containers in certain applications.

FIBCs are either coated or uncoated. Uncoated FIBCs are breathable and allow transmission of moisture through the fabric. Coated FIBCs can restrict transmission of moisture; prevent dust escaping as well as having other special properties.

Control of ESD from fabrics can be done with either conductive or dissipative materials. If ESD control is poor or non existing, spark, brush and propagating brush discharges can create incendiary discharges in many common flammable atmospheres. In contrast the corona discharges are generally below incendiary discharge energy level.

Conductive fabrics require an electrically sufficient connection to a ground point. Any disruption in the ground connection disables their ESD control ability. Additionally, fabrication of containers formed of conductive fabrics requires specialized construction techniques to ensure all conductive surfaces are electrically connected together for a ground source.

In contrast, dissipative fabrics rely on the fabric, alone or in conjunction with an antistatic coating, to discharge charges at levels below minimum ignition energy of possibly flammable or explosive material.

The fabrics disclosed in U.S. Pat. No. 5,512,355, Fuson and assigned to E. I. duPont, comprise polypropylene yarns interwoven with sheath-core filament yarns. The sheath-core filament yarns further comprise semi-conductor carbon black or graphite containing core and a non-conducting sheath. The filaments are interlaced in the fabric at between ¼ and 2 inch intervals. In a preferred embodiment, the filaments are crimped so that stretching of the sheath-core yarn does not break the electrical continuity of the semi-conductor core. A noted disadvantage of sheath-core filaments is the relatively high cost of resultant yarns.

The fabrics disclosed (but not claimed) in the Linq Industries assigned patents, U.S. Pat. No. 5,478,154 to Pappas et al., U.S. Pat. No. 5,679,449 to Ebadat et al., and U.S. Pat. No. 6,112,772 to Ebadat et al., also comprise sheath-core yarns interwoven with non-conductive yarns or superimposed over non-conductive yarns. Such fabrics are identified as “quasi-conductive,” conduct electricity through the fabric and have surface resistivity of 10e9 to 10e12 ohms per square and the sheath-core yarns are identified as “quasi-conductive” with a resistance of 10e8 ohms per meter. In order to attain the disclosed surface resistivity an antistatic coating is utilized. Without antistatic coating, the sheath-core yarns must be placed at a narrow spacing with the effective discharge area between the sheath-core yarns limited to 9 mm.

These patents teach against the use of conductive fibers in ungrounded antistatic applications. When relying upon the sheath-core yarns for static dissipation these fabrics are costly.

U.S. Pat. No. 5,071,699 to Pappas et al. discloses the use of conductive fibers in ungrounded antistatic fabric further comprising an antistatic coating. The resultant surface resistivity of the fabric is 1.75 times 10e13 to 9.46 times 10e13 ohms. When the coating is not present the disclosed fabrics do not adequately dissipate static charges. As a result, care must be taken to preserve the integrity of the coating.

The above patents are incorporated by reference. It is seen from the above that what is needed is an electrostatic dissipative fabric that does not rely upon antistatic or conductive filament yarns.

DE Patent No. 39 38 414 C2 discloses a container for bulk material made of an electrically conducting fabric that consists of synthetic fibers or synthetic threads and that includes electrically non-conducting as well as electrically conducting threads, where the electrically conducting threads are made of a polyolefin and contain dispersed carbon black and/or graphite and that are woven into both warp and weft.

A fabric of such kind is well suited for the strong mechanical strain that occurs when using the fabric for a flexible container for bulk material, and a carrier to dissipate the electrostatic charge is ensured through the electrically conducting threads woven into the fabric.

A fabric considered “electrically conducting” exhibits a dissipation resistance to ground of less than 10e8 ohms. Such a dissipation resistance is generally required for explosion protection measures based on various technical safety regulations, and also for flexible containers for bulk material made of Type “C” polypropylene fabric according to the classification of the German industrial research group “Brennbare Staube/Elektrostatik”. This classification has become accepted worldwide.

However, it has been observed that paradoxically such a low dissipation resistance of the fabric entails an adverse effect: due to its low resistance, charges can move rapidly and with a high charge density across the entire surface of the fabric and can suddenly discharge at a point where contact occurs with a charge carrier of an opposite charge for example, a grounded person. Thus, a ground connection always needs to be established prior to the filling procedures that could cause a charge separation, to ensure that if a charge comes into existence it can flow from the fabric immediately to ground. However, this ground connection has proven to be an impediment, because, for example, prior to filling, a container for bulk material has to be individually and manually grounded using a metal clip and a metal cable, and thereafter, the ground connection has to be manually removed. Furthermore, there is the risk of forgetting to make the ground connection due to carelessness.

GB Patent No. 21 01 559 A1 anticipates a container for bulk material that is manufactured of a fabric that has metal threads woven into it, where said threads are capable of discharging the electrostatic charge of the fabric.

The disadvantage of this solution is that the stretching behavior of metal fibers or threads deviates significantly from that of the remaining fabric. This can easily lead to breakage of the metal fibers and thus to an interruption in the discharge.

An additional risk is that the metal threads that are made of, e.g., copper, or iron, or alloys thereof, corrode in air. Due to such interruption points, the risk of a spark generation and explosion is increased significantly in case of a static charge.

As a result, it is seen that a more robust anti-static textile fabric capable of preventing high surface charge levels is desirable, particularly a fabric that does not rely upon narrow spacing of quasi-conductor yarns.

### SUMMARY OF THE INVENTION

It is an aim of the present invention to eliminate at least a part of the problems relating to the prior art and to provide a novel kind of ungrounded type multilayer packaging with a reduced energy of electrostatic discharge for packaging used in a combustible environment.

According to the invention, into a non conductive multilayer packaging material at least one polymeric thermoplastic electrostatic dissipating layer is incorporated, to give an electrostatic discharge energy attenuation of more than 40 dB. The material can be incorporated by co-extrusion, coating or lamination.

In particular for FIBC type D containers, an electrostatic dissipative thermoplastic layer is applied to the surface or surfaces of the fabric. This layer can be manufactured with commonly known manufacturing methods, such as blown film extrusion, cast film extrusion or direct extrusion coating.

In particular for RIBC containers, an electrostatic dissipative thermoplastic layer is formed during a co-extrusion process, typically multilayer blow molding extrusion process.

In particular for a flexible packaging, an electrostatic dissipative thermoplastic layer is formed to the surface or surfaces of the film during co-extrusion process.

More specifically, the present invention is characterized by what is stated in the characterizing part of claim 1.

Considerable advantages are obtained by means of the invention. In particular, excellent electrical properties are achieved without deterioration of the mechanical strength of the packaging.

The present IBCs can be used for carrying expandable polystyrene pellets, bulk solid powders such as sugar, flour, starch, titanium dioxide, adipic acid or other gas and powder materials.

Further aspects and advantages of the invention will appear from the following detailed description.

### BRIEF DESCRIPTION OF THE DRAWINGS

FIG. 1 shows schematically the layered structure of an embodiment of the invention;

FIG. 2 shows the measurement set up;

FIG. 3 shows the measurement circuit used for determining electrical properties of the materials; and

FIGS. 4 and 5 show graphically the obtained results, FIG. 4 indicating the typical discharge behavior of a standard FIBC surface and FIG. 5 the discharge energy dissipation from an IPE surface according to the present invention.

### DETAILED DESCRIPTION OF PREFERRED EMBODIMENTS

As indicated above, intermediate bulk containers are, according to the invention, converted to give electrostatic discharge energy attenuation more than 40 dB by adding special polymeric thermoplastic electrostatic dissipating layer.

The IBCs of the present invention comprise both rigid intermediate bulk containers (RIBCs) made of electrically non-conducting polymers, such as polypropylene or HDPE, and flexible intermediate bulk containers (FIBCs) made of woven fabrics, which are typically made of electrically non-conducting polymer such as polypropylene, HDPE or LLDPE. Multilayer flexible packages are commonly made of PE, PP and barrier polymers like PA and EVOH.

The electrostatic dissipative layer of the coating can be in middle and/or on outer surfaces of said thermoplastic coating. This thermoplastic coating has discharge attenuation effect i.e. reduced energy of the possible discharge.

The conductive fabric comprises an electrically dissipative thermoplastic multilayer coating on a polymeric layer, or a polymeric layer which is electrostatic dissipating as such.

The multilayer packaging according to the invention can be produced with multilayer extrusion with extrusion coating or with lamination.

The electrostatic dissipative surface coatings have to have enough positive and negative ions, which are neutralizing the charges at the surfaces. The inner surface dissipative layer of the fabric reduces the tribocharging of the fabric during filling and discharging of the granular or powder like product. This solution does not require grounding to function, which has been demonstrated in measurements according to the standard IEC 61340-4-4, discussed below in more detail in connection with the examples.

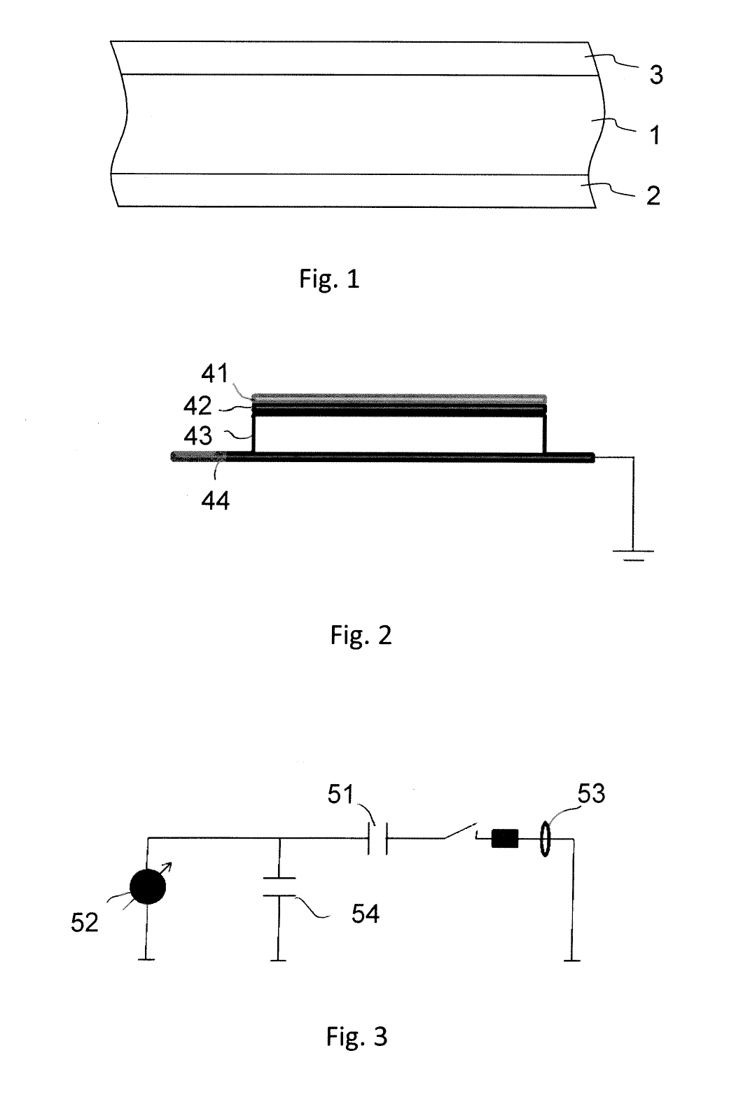

Turning now to the drawings, it can be noted that FIG. 1 shows a representative cross-sectional view of the wall of an embodiment of an IBC packaging according to the present invention.

The multilayered packaging product, generally designated with reference numerals 1-3, comprises at least one non-conductive layer for example formed by a film, fabric or sheath of a non-conductive material, and at least one dissipative layer. The dissipative layer can be located on either side or both sides of the non-conductive layer. There can be several polymer layers, typically formed by a thermoplastic polymer, separating the layer of the dissipative polymer and the non-conductive layer. Typically, the mechanical strength properties of the packaging are primarily derived from the non-conductive layer, although naturally all the other layers will contribute thereto also. Therefore, the non-conductive layer will also be referred to as the “structural” layer of the packaging.

In the drawing, the outer layer is given the numeral 3, the inner layer numeral 2 and the central, middle layer numeral 1. Depending on the actual configuration of the product layers, the non-conductive, structural layer can be located at 1, 2 or 3. However, it should be noted that in the product there is not always both an inner 2 and an outer layer 3. It is, viz., also possible to form a product wherein there is only an outer or an inner surface layer. That layer then comprises an electrostatic dissipative layer.

In one case, the non-conductive layer is located in the middle 1 of the product. The inner layer 2 is formed by the electrostatic dissipative thermoplastic coating. When the fabric 1 is used for flexible intermediate bulk containers (FIBC), the electrostatic dissipative thermoplastic polymer containing layer 2 is applied on the inner surface of said dissipative coating, i.e. on the surface abutting the contents of the container. The outer layer 3, which is optional, can be formed by another electrostatic dissipative thermoplastic coating, preferably the same material as used for the inner layer. It is also possible to provide a product of this kind without any specific outer layer 3, which means that the structural layer also forms the outer surface of the product.

In another embodiment, the outer layer 3 is formed by an electrostatic dissipative thermoplastic coating, and the non-conductive layer is located beneath it, forming the inner surface of the product (i.e. there is no separate inner layer 2).

In all of the above embodiments, the electrostatic dissipative thermoplastic coating can be formed by a layer of a dissipative polymer, of the kind discussed below in more detail potentially combined with one or several layers of thermoplastic polymers. Typically, the polymer is thermoplastic and preferably comprises the same polymer that forms the matrix of the dissipative thermoplastic coating, or it is a polymer that is compatible therewith.

For the purpose of FIBCs, the structural layer can be formed by any suitable non-conductive tapes. One embodiment of the invention comprises polypropylene non-conductive tapes. Common polypropylene tapes of 500 to 4000 denier and width of 1.7 mm to 10 mm are suitable. Polypropylene tapes narrower than 1.7 mm are often too thick and brittle for weaving into the fabric. Similarly polypropylene tapes wider than 10 mm are typically too thin and frequently break during weaving.

For the dissipative layer, various conductive materials can be used. Thus, in a first embodiment, the dissipative layer comprises a polymer having a polyethylene oxide block.

In a second embodiment, the electrically dissipative layer of said material comprises a polymer having polyethylene oxide and polyamide blocks.

In a third embodiment, the electrically dissipative layer of said material comprises a polymer having polyethylene oxide and polyester blocks.

In a fourth embodiment, the electrically dissipative layer of said material comprises a polymer having polyethylene oxide and polyurethane blocks.

In a fifth embodiment, the electrically dissipative layer of said material comprises a polymer having polyethylene oxide and polyolefin blocks.

Thus, the polymers including a polyether block are especially preferred. The polyether block is most suitably amorphous (non-crystalline). The molar mass (M_{w}) of the polyether block is preferably approx. 300-3000. The polyether block can for instance be polyethylene oxide or polypropylene oxide (in general polyalkylene oxide) or their copolymer. The “alkylene”-group contains most suitably 2-6 carbon atoms. Its part of the polymer is in general approx. 30-85 mass %, typically approx. 40-80 mass %.

The polymers may contains at least approx. 6 mass %, preferably at least 10 mass % polyether blocks of the layer weight. Most suitably the ionically conductive polymer layer contains polyether in an amount of 6-25 mass % of the total mass of the layer. The ionically conductive layer contains most suitably carboxylic acid or carboxylate in the amount of 0.1-10 mass % of the total mass of the layer.

As indicated, particularly preferred polymers are polyether block copolyesters, poly(ether ester amide)s, polyether block copolyamides and segmented polyether urethanes. The polyamide component may for example be PA-12 or PA-6, and the polyester component is typically polyethylene terephthalate.

Polymers suitable for the present invention are described for instance in the following patent specifications:

U.S. Pat. No. 2,623,031, U.S. Pat. No. 3,651,014, U.S. Pat. No. 3,763,109, U.S. Pat. No. 3,896,078, U.S. Pat. No. 4,115,475, U.S. Pat. No. 4,195,015, U.S. Pat. No. 4,230,838, U.S. Pat. No. 4,331,786, U.S. Pat. No. 4,332,920, U.S. Pat. No. 4,361,680, U.S. Pat. No. 4,719,263, U.S. Pat. No. 4,839,441, U.S. Pat. No. 4,864,014, U.S. Pat. No. 4,931,506, U.S. Pat. No. 5,101,139, U.S. Pat. No. 5,159,053, U.S. Pat. No. 5,298,558, U.S. Pat. No. 5,237,009, U.S. Pat. No. 5,342,889, U.S. Pat. No. 5,574,104, U.S. Pat. No. 5,604,284, U.S. Pat. No. 5,886,098, EP 0 613 919 A1 as well as in the PCT published application WO 03/000789,
the contents of which are incorporated into the present application by reference.

Commercially available polymers suitable for the invention and containing polyether include Atochem's Pebax, Ciba's Irgastat, Du Pont's Hytrel, Nippon Zeon's Hydrin, Noveon's Stat-rite, Sanyo Chemical's Pelestat and IPE of IonPhasE Oy.

Dissolvable cations according to the present invention are monovalent alkali metal ions, earth alkali metal ions, transition metal ions, mono-, di-, and trisubstituted imidazoles, substituted pyridium ions, substituted pyrrolidinium ions, tetraalkyl phosphoniums. Anions according to the invention are alkyl sulfate and alkyl sulphonate, tosylate ion, salicylate ion, triphlate ion, [CF₃CO₂]-, amide- and imide ions, bis(trifluorosulfon)imide, bis(toluenesulfon)imide, perchlorate ion.

The following can be mentioned as examples of suitable salts:

LiClO₄, LiCF₃SO₃, NaClO₄, LiBF₄, NaBF₄, KBF₄, NaCF₃SO₃, KClO₄, KPF₆, KCF₃SO₃, KC₄F₉SO₃, Ca(ClO₄)₂, Ca(PF₆)₂, Mg(ClO₄)₂, Mg(CF₃SO₃)₂, Zn(ClO₄)₂, Zn(PF6)₂ and Ca(CF₃SO₃)₂.

Monovalent, alkali metal ions are especially preferred. Lithium, sodium, potassium, rubidium and cesium are used as such or in combination with, e.g., earth alkali metal ions. Based on the foregoing, according to one embodiment, the electrically dissipative layer contains alkali ions 2 to 30 mmol/100 g of dissipative layer, preferably about 2 to 12 mmol/100 g of dissipative layer.

In another embodiment, the electrically dissipative layer contains anions 2 to 30 mmol/100 g of dissipative layer, preferably 3 to 12 mmol/100 g of dissipative layer.

In a further embodiment, the electrically dissipative layer contains potassium ions 2 to 30 mmol/100 g of dissipative layer, preferably 2-12 mmol/100 g of dissipative layer.

In still another embodiment, the electrically dissipative layer contains salicylate or tosylate ions 2 to 30 mmol/100 g of dissipative layer, preferably 2-12 mmol/100 g of dissipative layer.

The electrically dissipative layer contains electrostatic dissipative polymer 10-80%-mass, preferably 15-50%-mass.

The container material or fabric as such comprises typically a polyolefin or/and a barrier polymer such as polyamide or EVOH.

The polyolefins are suitably co-extrudable and blow moldable polymers. Examples of polyolefins are especially polypropylene (PP), polyisobutylene, polybut-1-ene, poly-4-methylpent-1-ene, polyisoprene, polybuthadiene, polycyclopentene, norbornene, as well as the polyethylenes (PE), high density polyethylene (HDPE), high molar mass polyethylene (HDPE-HMW), high density and ultra high molar mass polyethylene (HDPE-UHMW), medium density polyethylene (MDPE), low density polyethylene (LDPE), linear low density polyethylenes (LLDPE), (VLDPE) and (ULDPE). The polyesters are also easily melt processable, whereby polyethylene terephthalate, polybuthylene terephthalate as well as their compounds are particularly suitable.

Surprisingly, it has turned out that the static electricity dissipation of the thermoplastic layer limits the charging of the fabric thereby reducing charge density at the surfaces. Surprisingly, it has also been found that the electrostatic dissipative coating is able to neutralize and balance charges on the fabric surface thereby reducing the surface potential. Equally surprising, it has been determined that the electrostatic dissipative coating is capable of attenuating discharge energy from the surface.

These excellent electrical properties of the present invention will be examined in more detail.

The assessment of the occurrence and incendivity of discharges in industry by the laws of plasma physics a more or less phenomenological approach is commonly used. The discharges occurring in practice are classified into different discharge types. These types of discharges have different incendivities (igniting power). Every assessment of an ignition probability is based on a comparison of the incendivity of an electrostatic discharge with the sensitivity of the flammable atmosphere.

### Spark Discharges:

Spark discharges can occur between two conductors at different potential as soon as the electrical field in the gap reaches the breakdown threshold of about 3 MV/m at atmospheric conditions. Nearly all of the total energy stored in such systems (capacitors) is released in a single spark which generates a single discharge channel of high current density. Therefore these discharges are rather incendive and their energy release can be calculated by the energy stored on the capacitor (conductive material). W=½ CU²

In the present invention, a dissipative material, which has capability to attenuate the discharge energy, is used. Therefore spark discharges do not occur from the surface of the fabric.

### Brush Discharges:

Brush discharges can occur when earthed conducting objects approach highly charged non-conductive surfaces or materials. Brush discharges are known empirically to have an effective energy of as much as 4 mJ. Brush discharges may ignite gases and vapors.

In the present invention, a dissipative material with reduced surface resistance is used. Therefore brush discharges do not occur from the surface of the fabric.

### Propagating Brush Discharges:

Propagating brush discharges can occur from sheets or layers of a material of high resistivity and high dielectric strength with the two surfaces having a high surface charge density, but of opposite polarity.

In the present invention, a dissipative material with reduced surface resistance is used. The coated fabric also has same polarity of charge on both sides of the fabric. Therefore propagating brush discharges do not occur.

### Corona Discharge:

Corona discharges can occur if the field strength in front of a sharp point of a conductor exceeds the breakdown field strength for the medium (air for instance). This can happen if sharp conductor is given a high voltage or if grounded sharp conductor is brought near a charged object with high field strength. The rate and density of the energy dissipated in corona discharges is low and do not ignite powders nor gases and vapors of explosion group IIA and IIB. Ignition of gases and vapors of explosion group IIC cannot be ruled out.

The present invention is not based on corona discharging from conductive particles or threads.

Although the present invention has been described in terms of specific embodiments, various substitutions of materials and conditions can be made as will be known to those skilled in the art. For example, other polyolefin materials may be used for the non-conductive tapes of the fabric. Other variations will be apparent to those skilled in the art and are meant to be included herein. The scope of the invention is only to be limited by the claims set forth below.

### Example 1

### Lamination Film with Blown Film Extrusion

In a first trial, a lamination film have made with blown film extrusion line. In the test, a 3-layer blown film extrusion line have used. Two layers were for standard PP and one layer for dissipative polymer compound. Dissipative polymer compound amount was 40% of mass of dissipative layer. The thickness of the dissipative polymer layer was 5 um and the total film thickness was 30 um. This film was laminated on the inside and outside of a type-A FIBC surface and also on both surfaces.

### Example 2

### Lamination Film with Cast Film Extrusion

With this trial, a lamination film was made with cast film extrusion line. In the test, a 3-layer cast film extrusion line was used. Two layers were for standard PP and one layer for dissipative polymer compound. Dissipative polymer compound amount was 40% of mass of dissipative layer. The thickness of dissipative polymer compound layer was 4 um and the total film thickness was 35 um. This film was laminated the inside and outside of a type-A FIBC surface and also on both surfaces.

### Example 3

### On-Line Coating

The third trial was made with three layers on on-line coating. In the first and second layers standard PP was used and in the third layer a dissipative polymer compound was used. Dissipative polymer compound amount was 40% of mass of dissipative layer. The thickness of the PP layers was 25 um and of the thickness of the dissipative polymer compound layer was 3 um. In the trial, the first outer type-A FIBC surface was coated and then the inner layer was coated and finally both surfaces were coated.

### Example 4

### Coextrusion Sheet/Film

The trial was made with three layer coextrusion sheet line. In the first layer a dissipative polymer compound was used, standard HDPE was used in second and third layers. Dissipative polymer compound amount was 35% of mass of dissipative layer. The thickness of the outer layers was 50 um and of the thickness of the middle layer was 900 um.

### Example 5

### Coextrusion Sheet/Film

The trial was made with three layer coextrusion blown film line. In the first and third layers a dissipative polymer compound was used LLDPE was used in third layer. The thickness of the LLDPE layer was 55 um and of the thickness of the dissipative polymer compound layer was 3 um. Dissipative polymer compound amount was 35% of mass of dissipative layer.

### Example 6

The following measurements were made at an independent laboratory with the following setup. Measurements were carried out, when applicable, in reference with ISO/IEC/EN 17025 “General Requirements for the Competence of Calibration and Testing Laboratories”.

TABLE 2
Equipment

| Manufacturer | Type | Model |
|---|---|---|
| Tektronix | Oscilloscope | TDS 2022 |
| Tektronix | Current transformer | CT2 |
| Trek | High voltage generator | 610E |

TABLE 3
Test conditions

| Temperature | Relative Humidity | Stabilization of samples |
|---|---|---|
| 22 +/− 2 | 25% +/− 5% | 48 h |

The construction of the test arrangement is shown in the schematic depiction of FIG. 2.

Thus, the sample material 41 was placed on a charge plate 42, which was separated from the (grounded) ground plate 44 by an insulator 43, in this case a film of PTFE, poly(tetrafluoroethylene).

Dissipative polymer compound is containing Polyethyleneoxide block polymer 40 parts of weight, Polyethylene co-metacrylic acid polymer (potassium neutralized) 40 parts of weight and Polyester co-polymer 20 parts of weight.

The actual conditions were as follows:

TABLE 4
Measurement setup

| | Dimensions | Voltage | Capacitance | Resistance |
|---|---|---|---|---|
| | [mm] | [kV] | [pF] | [ohms] |
| Charge plate | 150 × 150 × 1 | 8 | | |
| PTFE insulator | 150 × 150 × 15 | | | |
| Test setup | | | 50 | |
| Probe | | | | 33 |

Note:
Probe shape has big influence on the discharge phenomenon. Small curvature (<2 mm) probe head was used in these measurements.

The measurement circuit used is shown in FIG. 3. In FIG. 3, reference numeral 51 stands for the sample which is to be tested, numeral 52 denotes a HV generator, 53 a current transformer and 54 a capacitor having a capacitance of 50 pF.

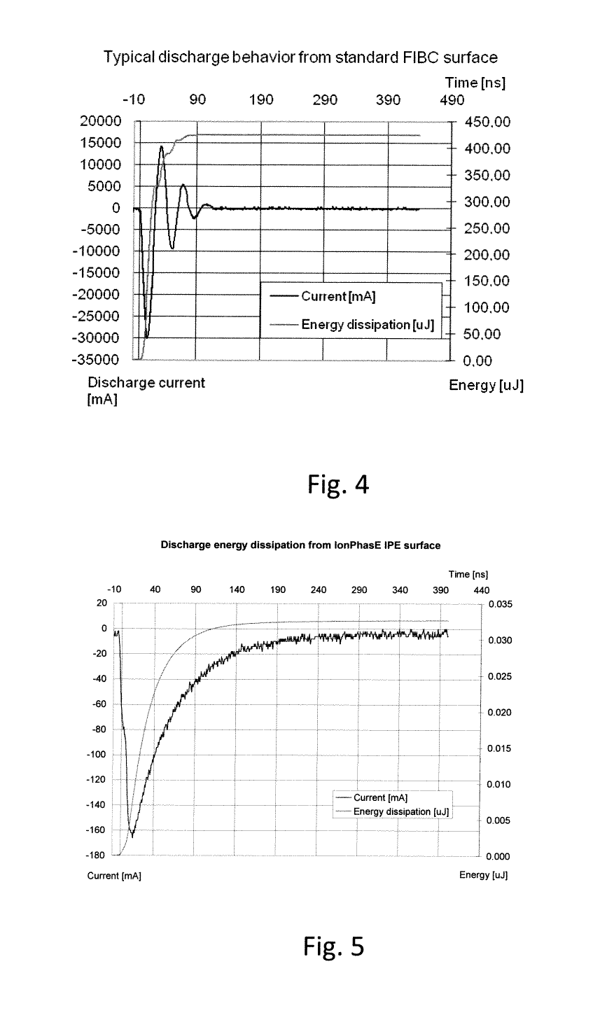

The results obtained are graphically shown in FIGS. 4 and 5.

As will appear from FIGS. 4 and 5, in comparison to a standard fabric, we were able to determine >40 db attenuation of the discharge energy [J] and >20 dB attenuation of peak current [A].

dB=10 log(A1/A2)=10 log(30000 mA/160 mA)=22.7 dB

dB=10 log(W1/W2)=10 log(420 uJ/0.032 uJ)=41.2 dB

### Discharge Incendivity Tests

For the different structures of Examples 1-5 discharge incendivity testing was performed based upon International Electrotechnical Commission Standard (IEC) 61340-4-4. All structures 1-5 passed the tests.

### Propagating Brush Discharge Test

All structures 1-5 also passed the Propagating brush discharge tests.

1. An ungrounded type multilayer packaging with a reduced energy of electrostatic discharge for packaging used in a combustible environment, said packaging comprising a nonconductive multilayer packaging material containing at least one polymeric thermoplastic electrostatic dissipating layer, to give an electrostatic discharge energy attenuation of more than 40 dB.

2. The packaging of claim 1, wherein the non-conductive material comprises an electrically dissipative thermoplastic multilayer coating on a polymeric layer, or a polymeric layer which is electrostatic dissipating as such.

3. The packaging of claim 1, wherein the electrically dissipative layer of said material comprises a polymer having a polyethylene oxide block.

4. The packaging of claim 1, wherein the electrically dissipative layer of said material comprises a polymer having polyethylene oxide and polyamide blocks.

5. The packaging of claim 1, wherein the electrically dissipative layer of said material comprises a polymer having polyethylene oxide and polyester blocks.

6. The packaging of claim 1, wherein the electrically dissipative layer of said material comprises a polymer having polyethylene oxide and polyurethane blocks.

7. The packaging of claim 1, wherein the electrically dissipative layer of said material comprises a polymer having polyethylene oxide and polyolefin blocks.

8. The packaging of claim 1, wherein an electrostatic dissipating layer is applied with lamination.

9. The packaging of claim 1, wherein the static dissipative layer is laminated into an inner surface of the fabric.

10. The packaging of claim 1, wherein the static dissipating layer is laminated into an outer surface of the fabric.

11. The packaging of claim 1, wherein the static dissipating layer is laminated into an inner and an outer surface of the fabric.

12. The packaging of claim 1, with a reduced energy of electrostatic discharge for use in a combustible environment without the need of grounding.

13. The packaging of claim 1, wherein the static dissipating layer has a multi layer structure, at least one of the layers having an electrostatic dissipating property.

14. The packaging of claim 1, wherein the electrostatic dissipating layer is formed by a coating having a total thickness of 5-100 micrometers, in particular 5-50 micrometers, preferably about 5 to 30 micrometers.

15. The packaging of any of claim 1, wherein the electrostatic dissipating layer of the multilayer packaging has total thickness of 1-100 micrometers.

16. The packaging of claim 2 wherein the electrostatic dissipating layer of electrostatic dissipative layer has total thickness of 2-10 micrometers.

17. The packaging of claim 1, wherein the electrically dissipative layer contains alkali ions 2-30 mmol/100 g of dissipative layer, preferably about 2 to 12 mmol/100 g of dissipative layer.

18. The packaging of claim 1, wherein the electrically dissipative layer contains anions 2-30 mmol/100 g of dissipative layer, preferably about 3 to 12 mmol/100 g of dissipative layer.

19. The packaging of claim 1, wherein the electrically dissipative layer contains potassium ions 2-30 mmol/100 g of dissipative layer, preferably about 2 to 12 mmol/100 g of dissipative layer.

20. The packaging of claim 1, wherein the electrically dissipative layer contains salicylate or tosylate ions 2-30 mmol/100 g of dissipative layer, preferably about 2 to 12 mmol/100 g of dissipative layer.

21. The packaging of any of claims 1 to 20, wherein the electrically dissipative layer contains electrostatic dissipative polymer 10-80%-mass, preferably 15-50%-mass.

22. (canceled)

23. (canceled)

24. (canceled)

25. (canceled)

26. (canceled)

27. (canceled)

28. (canceled)
